(19) United States
(12) Patent Application Publication
(10) Pub. No.: US 2024/0419870 A1
(43) Pub. Date: Dec. 19, 2024

(54) VIBRATION SIGNAL MODULATION METHOD AND SYSTEM BASED ON PARTICLE SWARM OPTIMIZATION, AND RELATED DEVICE

(71) Applicant: AAC Acoustic Technologies (Shanghai) Co., Ltd., Shanghai (CN)

(72) Inventors: Shiyu Pei, Shanghai (CN); Yajun Zheng, Shanghai (CN)

(21) Appl. No.: 18/404,828

(22) Filed: Jan. 4, 2024

Related U.S. Application Data
(63) Continuation of application No. PCT/CN2023/100584, filed on Jun. 16, 2023.

(51) Int. Cl. G06F 30/25

(52) U.S. Cl. CPC G06F 30/25

(57) ABSTRACT

A vibration signal modulation method includes following steps: setting a signal accelerating section parameter according to an expected vibration signal of an application object; setting a corresponding signal braking section parameter and a signal braking section parameter range, constructing a braking section initial particle parameter for a particle swarm algorithm, and performing an iterative search within the signal braking section parameter range to obtain an optimum braking parameter; and superposing a signal corresponding to the optimum braking parameter on a signal corresponding to the signal accelerating section parameter to obtain a final vibration signal. Compared with the related art, in the present disclosure, the signal accelerating section parameter is set, and a to-be-optimized particle swarm is set based on existing parameters. With a particle swarm optimization method, a braking section parameter is searched for, so that a vibration signal matching a current application object can be quickly found.

### CROSS-REFERENCE TO RELATED APPLICATIONS

This application is a continuation of International Application No. PCT/CN2023/100584, filed on Jun. 16, 2023, which is hereby incorporated by reference in its entirety.

### TECHNICAL FIELD

The present disclosure relates to the technical field of signal modulation, and in particular, to a vibration signal modulation method based on particle swarm optimization, a vibration signal modulation system based on particle swarm optimization, a computer device and a computer-readable storage medium.

### BACKGROUND

Due to increasing application scenes of vibration devices, application examples of the vibration devices can be seen not only on mobile phones and handles, but also on vehicle steering wheels and screens.

In the application scenes of the vibration devices, different application objects have different structures. To enable the vibration devices to perfectly match different structures, there is a need to establish corresponding mechanism models to express vibration transfer according to different application objects, which is a challenge for a method and efficiency of vibration signal design.

However, in the related art, a vibration signal modulation method is limited by a modulation process and an application device. In a signal modulation stage, an adaptive mechanism model cannot be established according to an application object, resulting in a poor effect of a finally modulated vibration signal and low efficiency of the modulation process.

Therefore, it is necessary to provide a new vibration signal modulation method to solve the above problems.

### SUMMARY

In order to solve the above technical problem, a first aspect of the present disclosure provides a vibration signal modulation method based on particle swarm optimization. The vibration signal modulation method includes the following steps:
setting a signal accelerating section parameter according to an expected vibration signal of an application object;
setting a corresponding signal braking section parameter and a signal braking section parameter range according to the signal accelerating section parameter, constructing, based on the signal braking section parameter range, a braking section initial particle parameter for a particle swarm algorithm, and performing, based on the particle swarm algorithm, an iterative search within the signal braking section parameter range to obtain an optimum braking parameter; and
superposing a signal corresponding to the optimum braking parameter on a signal corresponding to the signal accelerating section parameter to obtain a final vibration signal for the application object.

In an embodiment, a particle swarm parameter includes: a maximum iteration generation, a preset iteration stop condition, a population number, a variable number, and an update constant;
default configuration parameters for the particle swarm algorithm includes: a signal sampling rate, an actuator resonant frequency, a vibrator maximum displacement, and an actuator parameter;
the signal accelerating section parameter includes: a signal production frequency, an accelerating section cycle, and an accelerating section voltage; and
the signal braking section parameter includes: a braking cycle, a braking voltage, and a braking start position.

In an embodiment, the setting a corresponding signal braking section parameter and a signal braking section parameter range according to the signal accelerating section parameter, constructing, based on the signal braking section parameter range, a braking section initial particle parameter for a particle swarm algorithm, and performing, based on the particle swarm algorithm, an iterative search within the signal braking section parameter range to obtain an optimum braking parameter includes the following sub-steps:
setting the corresponding signal braking section parameter and the signal braking section parameter range according to the signal accelerating section parameter, and constructing, based on the signal braking section parameter range, the braking section initial particle parameter for the particle swarm algorithm;
superposing a single-frequency signal generated according to the signal accelerating section parameter on a single-frequency signal generated according to the signal braking section parameter for integration to obtain an excitation electrical signal, driving the excitation electrical signal to the application object to obtain an acceleration waveform, and calculating a tailing factor of the acceleration waveform;
determining a current-generation best particle of the particle swarm algorithm based on the tailing factor, the current-generation best particle including a global best particle and personal best particles, and setting the signal braking section parameter range used to constrain the signal braking section parameter, wherein, if a number of iterations of the particle swarm algorithm is 1, the braking section initial particle parameter is taken as an personal best particle, and one of the personal best particles with a minimum tailing factor is taken as the global best particle;
calculating, within the signal braking section parameter range, an update speed and an update position of a current particle based on the current-generation best particle to obtain a next-generation particle, and calculating a tailing factor corresponding to the next-generation particle to obtain a next-generation best particle; and
determining whether a tailing factor of the next-generation best particle satisfies the preset iteration stop condition:
if not, updating the global best particle and the personal best particles with the next-generation best particle, which is taken as a new current-generation best particle to iteratively perform an update search; and
if yes, outputting the next-generation best particle as the optimum braking parameter.

In an embodiment, it is defined that the update speed is Vₖ and the update position is popₖ, and the following relations are satisfied:

$${V}_{k} = w \cdot {V}_{k - 1} + c 1 \cdot rand ( pbest - {pop}_{k - 1} ) + c 2 \cdot rand ( gbest - {pop}_{k - 1} ) ; \\ {pop}_{k} = {pop}_{k - 1} + {V}_{k} ;$$

where gbest denotes the global best particle, pbest denotes the personal best particle, k denotes an iteration generation of the particle swarm algorithm, rand( ) denotes a random number generation function, c1 and c2 denote the update constants, w denotes a preset weight, and the preset weight w satisfies:

$$w = \frac{maxgen - k}{maxgen} * ( 0.4 - 0.9 ) + 0.9 ;$$

maxgen denotes the maximum iteration generation.

In an embodiment, the update position and the signal accelerating section parameter are integrated to obtain an excitation signal, a vibrator displacement of the application object is calculated, and if the vibrator displacement is greater than the vibrator maximum displacement,
the braking cycle and the braking voltage are compressed; or
the braking voltage is reversely varied.

In an embodiment, the preset iteration stop condition is specifically:
the tailing factor corresponding to the optimum next-generation particle satisfying a preset stop ratio, or the current iteration generation satisfying the maximum iteration generation.

A second aspect of the present disclosure further provides a vibration signal modulation system based on particle swarm optimization. The system includes:
a parameter setting module configured to set a signal accelerating section parameter according to an expected vibration signal of an application object;
a particle swarm optimization module configured to set a corresponding signal braking section parameter and a signal braking section parameter range according to the signal accelerating section parameter, construct, based on the signal braking section parameter range, a braking section initial particle parameter for a particle swarm algorithm, and perform, based on the particle swarm algorithm, an iterative search within the signal braking section parameter range to obtain an optimum braking parameter; and
an output module configured to superpose a signal corresponding to the optimum braking parameter on a signal corresponding to the signal accelerating section parameter to obtain a final vibration signal for the application object.

In an embodiment, a particle swarm parameter includes: a maximum iteration generation, a preset iteration stop condition, a population number, a variable number, and an update constant;
default configuration parameters for the particle swarm algorithm includes: a signal sampling rate, an actuator resonant frequency, a vibrator maximum displacement, and an actuator parameter;
the signal accelerating section parameter includes: a signal production frequency, an accelerating section cycle, and an accelerating section voltage; and
the particle swarm optimization module is specifically configured to:
set the corresponding signal braking section parameter and the signal braking section parameter range according to the signal accelerating section parameter, and construct, based on the signal braking section parameter range, the braking section initial particle parameter for the particle swarm algorithm;
superpose a single-frequency signal generated according to the signal accelerating section parameter on a single-frequency signal generated according to the signal braking section parameter for integration to obtain an excitation electrical signal, drive the excitation electrical signal to the application object to obtain an acceleration waveform, and calculate a tailing factor of the acceleration waveform;
determine a current-generation best particle of the particle swarm algorithm, the current-generation best particle including a global best particle and personal best particles, and set the signal braking section parameter range used to constrain the signal braking section parameter, wherein, if a number of iterations of the particle swarm algorithm is 1, the braking section initial particle parameter is taken as an personal best particle, and one of the personal best particles with a minimum tailing factor is taken as the global best particle;
calculate, within the signal braking section parameter range, an update speed and an update position of a current particle based on the current-generation best particle to obtain a next-generation particle, and calculate a tailing factor corresponding to the next-generation particle to obtain a next-generation best particle; and
determine whether a tailing factor of the next-generation best particle satisfies the preset iteration stop condition:
if not, update the global best particle and the personal best particles with the next-generation best particle, which is taken as a new current-generation best particle to iteratively perform an update search; and
if yes, output the next-generation best particle as the optimum braking parameter.

A third aspect of the present disclosure provides a computer device. The computer device includes: a memory, a processor, and a vibration signal modulation program based on particle swarm optimization stored in the memory and executable by the processor. The processor, when executing the vibration signal modulation program based on particle swarm optimization, implements steps in the vibration signal modulation method based on particle swarm optimization as described in any one of the above.

A fourth aspect of the present disclosure provides a computer-readable storage medium. The computer-readable storage medium stores a vibration signal modulation program based on particle swarm optimization. When the vibration signal modulation program based on particle swarm optimization is executed by a processor, steps in the vibration signal modulation method based on particle swarm optimization as described in any one of the above are implemented.

### BRIEF DESCRIPTION OF DRAWINGS

In order to illustrate the technical solutions in the embodiments of the present disclosure more clearly, the accompanying drawings to be used in the description of the embodiments will be briefly introduced below. The accompanying drawings in the following description are only some embodiments of the present disclosure. For those skilled in the art, other accompanying drawings can be obtained based on these drawings. In the drawings,

FIG. 1 is a flow block diagram of steps of a vibration signal modulation method based on particle swarm optimization according to an embodiment of the present disclosure;

FIG. 2 is a schematic diagram of convergence of a particle swarm optimization algorithm of a vibration signal modulation method based on particle swarm optimization according to an embodiment of the present disclosure;

FIG. 3 is a schematic diagram of a waveform of a final vibration signal according to an embodiment of the present disclosure;

FIG. 4 is a schematic structural diagram of a vibration signal modulation system based on particle swarm optimization according to an embodiment of the present disclosure; and

FIG. 5 is a schematic structural diagram of a computer device according to an embodiment of the present disclosure.

### DESCRIPTION OF EMBODIMENTS

The technical solutions in the embodiments of the present disclosure will be clearly and completely described below with reference to the accompanying drawings in the embodiments of the present disclosure. The described embodiments are only some of the embodiments of the present disclosure, but not all of the embodiments. Based on the embodiments of the present disclosure, all other embodiments obtained by those skilled in the art fall within the protection scope of the present disclosure.

### Embodiment 1

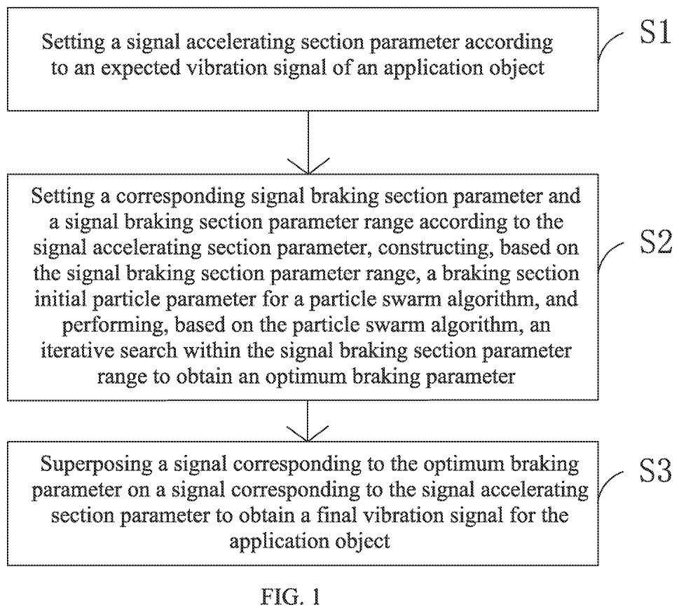

Referring to FIG. 1, FIG. 1 is a flow block diagram of steps of a vibration signal modulation method based on particle swarm optimization according to an embodiment of the present disclosure. The vibration signal modulation method includes the following steps.

In S1, a signal accelerating section parameter is set according to an expected vibration signal of an application object.

In S2, a corresponding signal braking section parameter and a signal braking section parameter range are set according to the signal accelerating section parameter, a braking section initial particle parameter for a particle swarm algorithm is constructed based on the signal braking section parameter range, and based on the particle swarm algorithm, an iterative search is performed within the signal braking section parameter range to obtain an optimum braking parameter.

In an embodiment, a particle swarm parameter includes: a maximum iteration generation, a preset iteration stop condition, a population number, a variable number, and an update constant;
default configuration parameters for the particle swarm algorithm includes: a signal sampling rate, an actuator resonant frequency, a vibrator maximum displacement, and an actuator parameter;
the signal accelerating section parameter includes: a signal production frequency, an accelerating section cycle, and an accelerating section voltage; and
the signal braking section parameter includes: a braking cycle, a braking voltage, and a braking start position.

In this embodiment of the present disclosure, the signal accelerating section parameter and the signal braking section parameter are relative to a vibration motor. In other words, in this embodiment of the present disclosure, accelerating and braking parameters of the vibration motor are controlled to achieve control over the motor and generate a corresponding vibration signal. That is, in the above default configuration parameters, the actuator resonant frequency and the actuator parameter corresponding to a motor resonant frequency and an actuator parameter respectively.

In an embodiment, the setting a corresponding signal braking section parameter and a signal braking section parameter range according to the signal accelerating section parameter, constructing, based on the signal braking section parameter range, a braking section initial particle parameter for a particle swarm algorithm, and performing, based on the particle swarm algorithm, an iterative search within the signal braking section parameter range to obtain an optimum braking parameter includes the following sub-steps:
setting the corresponding signal braking section parameter and the signal braking section parameter range according to the signal accelerating section parameter, and constructing, based on the signal braking section parameter range, the braking section initial particle parameter for the particle swarm algorithm;
superposing a single-frequency signal generated according to the signal accelerating section parameter on a single-frequency signal generated according to the signal braking section parameter for integration to obtain an excitation electrical signal, driving the excitation electrical signal to the application object to obtain an acceleration waveform, and calculating a tailing factor of the acceleration waveform;
determining a current-generation best particle of the particle swarm algorithm based on the tailing factor, the current-generation best particle including a global best particle and personal best particles, and setting the signal braking section parameter range used to constrain the signal braking section parameter, wherein, if a number of iterations of the particle swarm algorithm is 1, the braking section initial particle parameter is taken as an personal best particle, and one of the personal best particles with a minimum tailing factor is taken as the global best particle;
calculating, within the signal braking section parameter range, an update speed and an update position of a current particle based on the current-generation best particle to obtain a next-generation particle, and calculating a tailing factor corresponding to the next-generation particle to obtain a next-generation best particle; and
determining whether a tailing factor of the next-generation best particle satisfies the preset iteration stop condition:
if not, updating the global best particle and the personal best particles with the next-generation best particle, which is taken as a new current-generation best particle to iteratively perform an update search; and
if yes, outputting the next-generation best particle as the optimum braking parameter.

In this embodiment of the present disclosure, the tailing factor is a parameter used to evaluate a vibration signal after optimization and a vibration signal before optimization. During actual implementation, acceleration generated by the motor through a superposed signal may be compared through a signal collection device. For example, if it is defined that the tailing factor of stopping acceleration at which a superposed signal of the signal accelerating section parameter and the braking section initial particle parameter finally drives the vibration device to be applied to an actual object is r, r=Glast/Gpp, where Glast denotes an acceleration peak after vibration of the vibration device ends, i.e., a tailing size; Gpp denotes an acceleration peak-to-peak value corresponding to an entire signal driving the vibration device. In this embodiment of the present disclosure, the search is intended to minimize a tailing factor of corresponding acceleration of a target excitation signal on the application object to produce best vibration experience.

In an embodiment, it is defined that the update speed is Vₖ and the update position is popₖ, and the following relations are satisfied:

$${V}_{k} = w \cdot {V}_{k - 1} + c 1 \cdot rand ( pbest - {pop}_{k - 1} ) + c 2 \cdot rand ( gbest - {pop}_{k - 1} ) ; \\ {pop}_{k} = {pop}_{k - 1} + {V}_{k} ;$$

where gbest denotes the global best particle, pbest denotes the personal best particle, k denotes an iteration generation of the particle swarm algorithm, rand( ) denotes a random number generation function, c1 and c2 denote the update constants, w denotes a preset weight, and the preset weight w satisfies:

$$w = \frac{maxgen - k}{maxgen} * ( 0.4 - 0.9 ) + 0.9 ;$$

maxgen denotes the maximum iteration generation.

In an embodiment, the update position and the signal accelerating section parameter are integrated to obtain an excitation signal, a vibrator displacement of the application object is calculated, the update position is an updated braking section parameter, and if the vibrator displacement is greater than the vibrator maximum displacement,
the braking cycle and the braking voltage are compressed;
or
the braking voltage is reversely varied.

This step is to protect the application object, that is, displacement of a motor device, and is used to reasonably adjust a particle update position. In an embodiment, it is determined whether given maximum displacement of a motor vibrator may be exceeded by driving the motor with an excitation signal obtained according to the update position, and if yes, the update position is required to be adjusted in the above manner. It is to be noted that this step is required both in initialization of a particle position and in subsequent iterative updates of the particle position.

In an embodiment, the preset iteration stop condition is specifically:

the tailing factor corresponding to the optimum next-generation particle satisfying

a preset stop ratio, or the current iteration generation satisfying the maximum iteration generation.

In S3, a signal corresponding to the optimum braking parameter is superposed on a signal corresponding to the signal accelerating section parameter to obtain a final vibration signal for the application object.

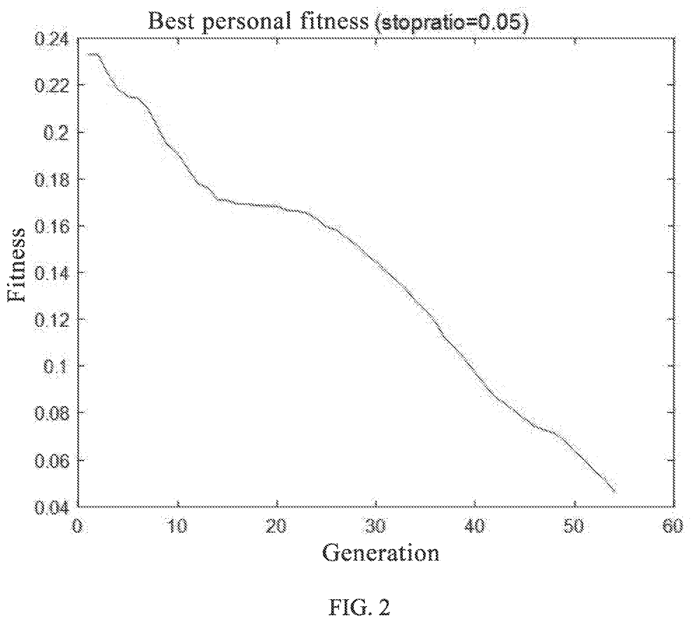

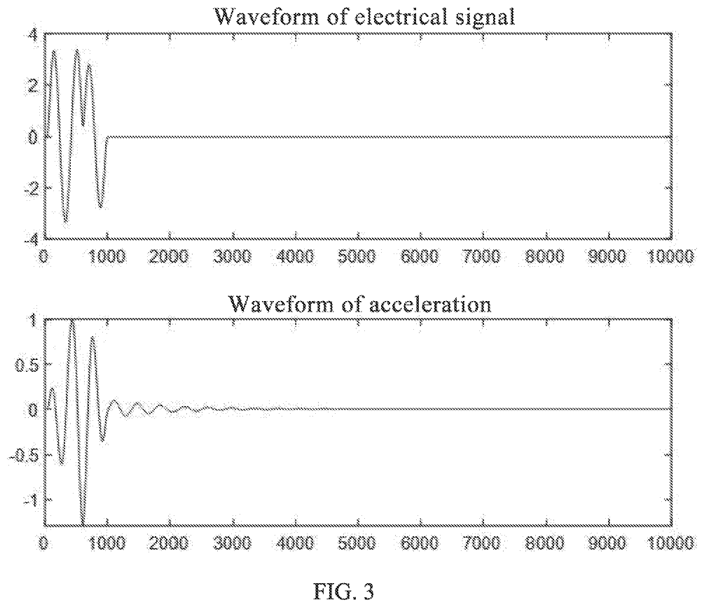

Exemplarily, in this embodiment of the present disclosure, a particle swarm optimization is designed as follows. The maximum iteration generation maxgen is 100, the preset iteration stop condition stopratio is 0.05, the population number is 50, the variable number n is 3, and the update constant c1=c2=2. FIG. 2 and FIG. 3 are schematic diagrams of waveforms of convergence and a final vibration signal respectively. As can be seen, in this embodiment of the present disclosure, a vibration signal matching acceleration of the application object can be obtained with the particle swarm optimization method.

Compared with the related art, the vibration signal modulation method based on particle swarm optimization in the present disclosure includes the following steps: setting a signal accelerating section parameter according to an expected vibration signal of an application object; setting a corresponding signal braking section parameter and a signal braking section parameter range according to the signal accelerating section parameter, constructing, based on the signal braking section parameter range, a braking section initial particle parameter for a particle swarm algorithm, and performing, based on the particle swarm algorithm, an iterative search within the signal braking section parameter range to obtain an optimum braking parameter; and superposing a signal corresponding to the optimum braking parameter on a signal corresponding to the signal accelerating section parameter to obtain a final vibration signal for the application object. The signal accelerating section parameter is set, and a to-be-optimized particle swarm is set based on existing parameters. With a particle swarm optimization method, a braking section parameter is searched for, so that a vibration signal matching a current application object can be quickly found.

### Embodiment 2

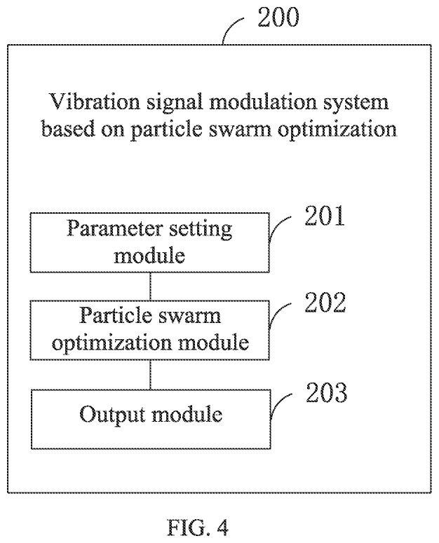

The present disclosure further provides a vibration signal modulation system based on particle swarm optimization. Referring to FIG. 4, FIG. 4 is a schematic structural diagram of a vibration signal modulation system based on particle swarm optimization according to an embodiment of the present disclosure. The vibration signal modulation system based on particle swarm optimization 200 includes:
a parameter setting module 201 configured to set a signal accelerating section parameter according to an expected vibration signal of an application object;
a particle swarm optimization module 202 configured to set a corresponding signal braking section parameter and a signal braking section parameter range according to the signal accelerating section parameter, construct, based on the signal braking section parameter range, a braking section initial particle parameter for a particle swarm algorithm, and perform, based on the particle swarm algorithm, an iterative search within the signal braking section parameter range to obtain an optimum braking parameter; and
an output module 203 configured to superpose a signal corresponding to the optimum braking parameter on a signal corresponding to the signal accelerating section parameter to obtain a final vibration signal for the application object.

The particle swarm parameter includes: a maximum iteration generation, a preset iteration stop condition, a population number, a variable number, and an update constant.

Default configuration parameters for the particle swarm algorithm includes: a signal sampling rate, an actuator resonant frequency, a vibrator maximum displacement, and an actuator parameter.

In an embodiment, the signal accelerating section parameter includes: a signal production frequency, an accelerating section cycle, and an accelerating section voltage.

The particle swarm optimization module is specifically configured to:
set the corresponding signal braking section parameter and the signal braking section parameter range according to the signal accelerating section parameter, and construct, based on the signal braking section parameter range, the braking section initial particle parameter for the particle swarm algorithm;
superpose a single-frequency signal generated according to the signal accelerating section parameter on a single-frequency signal generated according to the signal braking section parameter for integration to obtain an excitation electrical signal, drive the excitation electrical signal to the application object to obtain an acceleration waveform, and calculate a tailing factor of the acceleration waveform;
determine a current-generation best particle of the particle swarm algorithm based on the tailing factor, the current-generation best particle including a global best particle and personal best particles, and set the signal braking section parameter range used to constrain the signal braking section parameter, wherein, if a number of iterations of the particle swarm algorithm is 1, the braking section initial particle parameter is taken as an personal best particle, and one of the personal best particles with a minimum tailing factor is taken as the global best particle;
calculate, within the signal braking section parameter range, an update speed and an update position of a current particle based on the current-generation best particle to obtain a next-generation particle, and calculate a tailing factor corresponding to the next-generation particle to obtain a next-generation best particle; and
determine whether a tailing factor of the next-generation best particle satisfies the preset iteration stop condition:
if not, update the global best particle and the personal best particles with the next-generation best particle, which is taken as a new current-generation best particle to iteratively perform an update search; and
if yes, output the next-generation best particle as the optimum braking parameter.

In an embodiment, it is defined that the update speed is Vₖ and the update position is popₖ, and the following relations are satisfied:

$${V}_{k} = w \cdot {V}_{k - 1} + c 1 \cdot rand ( pbest - {pop}_{k - 1} ) + c 2 \cdot rand ( gbest - {pop}_{k - 1} ) ; \\ {pop}_{k} = {pop}_{k - 1} + {V}_{k} ;$$

where gbest denotes the global best particle, pbest denotes the personal best particle, k denotes an iteration generation of the particle swarm algorithm, rand( ) denotes a random number generation function, c1 and c2 denote the update constants, w denotes a preset weight, and the preset weight w satisfies:

$$w = \frac{maxgen - k}{maxgen} * ( 0.4 - 0.9 ) + 0.9 ;$$

maxgen denotes the maximum iteration generation.

In an embodiment, the update position and the signal accelerating section parameter are integrated to obtain an excitation signal, a vibrator displacement of the application object is calculated, and if the vibrator displacement is greater than the vibrator maximum displacement,
the braking cycle and the braking voltage are compressed; or
the braking voltage is reversely varied.

In an embodiment, the preset iteration stop condition is specifically:
the tailing factor corresponding to the optimum next-generation particle satisfying

a preset stop ratio, or the current iteration generation satisfying the maximum iteration generation.

The vibration signal modulation system based on particle swarm optimization 200 can implement steps in the vibration signal modulation method based on particle swarm optimization in the above embodiments, and can achieve the same technical effect. Refer to the description in the above embodiments. Details are not described herein again.

### Embodiment 3

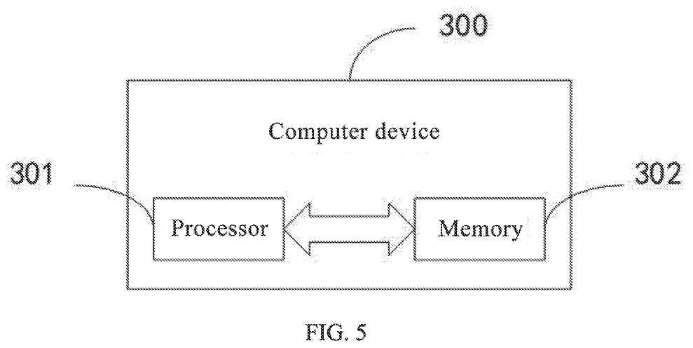

An embodiment of the present disclosure further provides a computer device. Referring to FIG. 5, FIG. 5 is a schematic structural diagram of a computer device according to an embodiment of the present disclosure. The computer device 300 includes: a memory 302, a processor 301, and a computer program stored in the memory 302 and executable by the processor 301.

The processor 301 calls the computer program stored in the memory 302 to perform steps in the vibration signal modulation method based on particle swarm optimization provided in the embodiments of the present disclosure. Referring to FIG. 1, the method specifically includes the following steps.

In S1, a signal accelerating section parameter is set according to an expected vibration signal of an application object.

In S2, a corresponding signal braking section parameter and a signal braking section parameter range are set according to the signal accelerating section parameter, a braking section initial particle parameter for a particle swarm algorithm is constructed based on the signal braking section parameter range, and based on the particle swarm algorithm, an iterative search is performed within the signal braking section parameter range to obtain an optimum braking parameter.

In an embodiment, the particle swarm parameter includes: a maximum iteration generation, a preset iteration stop condition, a population number, a variable number, and an update constant;
default configuration parameters for the particle swarm algorithm includes: a signal sampling rate, an actuator resonant frequency, a vibrator maximum displacement, and an actuator parameter;
the signal accelerating section parameter includes: a signal production frequency, an accelerating section cycle, and an accelerating section voltage; and
the signal braking section parameter includes: a braking cycle, a braking voltage, and a braking start position.

In an embodiment, the setting a corresponding signal braking section parameter and a signal braking section parameter range according to the signal accelerating section parameter, constructing, based on the signal braking section parameter range, a braking section initial particle parameter for a particle swarm algorithm, and performing, based on the particle swarm algorithm, an iterative search within the signal braking section parameter range to obtain an optimum braking parameter includes the following sub-steps:
setting the corresponding signal braking section parameter and the signal braking section parameter range according to the signal accelerating section parameter, and constructing, based on the signal braking section parameter range, the braking section initial particle parameter for the particle swarm algorithm;
superposing a single-frequency signal generated according to the signal accelerating section parameter on a single-frequency signal generated according to the signal braking section parameter for integration to obtain an excitation electrical signal, driving the excitation electrical signal to the application object to obtain an acceleration waveform, and calculating a tailing factor of the acceleration waveform;
determining a current-generation best particle of the particle swarm algorithm based on the tailing factor, the current-generation best particle including a global best particle and personal best particles, and setting the signal braking section parameter range used to constrain the signal braking section parameter, wherein, if a number of iterations of the particle swarm algorithm is 1, the braking section initial particle parameter is taken as an personal best particle, and one of the personal best particles with a minimum tailing factor is taken as the global best particle;
calculating, within the signal braking section parameter range, an update speed and an update position of a current particle based on the current-generation best particle to obtain a next-generation particle, and calculating a tailing factor corresponding to the next-generation particle to obtain a next-generation best particle; and

determining whether a tailing factor of the next-generation best particle satisfies the preset iteration stop condition:

if not, taking the next-generation best particle as a new current-generation best particle to iteratively perform an update search; and

if yes, outputting the next-generation best particle as the optimum braking parameter.

In an embodiment, it is defined that the update speed is Vₖ and the update position is popₖ, and the following relations are satisfied:

$${V}_{k} = w \cdot {V}_{k - 1} + c 1 \cdot rand ( pbest - {pop}_{k - 1} ) + c 2 \cdot rand ( gbest - {pop}_{k - 1} ) ; \\ {pop}_{k} = {pop}_{k - 1} + {V}_{k} ;$$

where gbest denotes the global best particle, pbest denotes the personal best particle, k denotes an iteration generation of the particle swarm algorithm, rand( ) denotes a random number generation function, c1 and c2 denote the update constants, w denotes a preset weight, and the preset weight w satisfies:

$$w = \frac{maxgen - k}{maxgen} * ( 0.4 - 0.9 ) + 0.9 ;$$

maxgen denotes the maximum iteration generation.

In an embodiment, the update position and the signal accelerating section parameter are integrated to obtain an excitation signal, a vibrator displacement of the application object is calculated, and if the vibrator displacement is greater than the vibrator maximum displacement,
the braking cycle and the braking voltage are compressed; or
the braking voltage is reversely varied.

In an embodiment, the preset iteration stop condition is specifically:
the tailing factor corresponding to the optimum next-generation particle satisfying a preset stop ratio, or the current iteration generation satisfying the maximum iteration generation.

In S3, a signal corresponding to the optimum braking parameter is superposed on a signal corresponding to the signal accelerating section parameter to obtain a final vibration signal for the application object.

The computer device 300 provided in this embodiment of the present disclosure can implement steps in the vibration signal modulation method based on particle swarm optimization in the above embodiments, and can achieve the same technical effect. Refer to the description in the above embodiments. Details are not described herein again.

### Embodiment 4

An embodiment of the present disclosure further provides a computer-readable storage medium. The computer-readable storage medium stores a vibration signal modulation program based on particle swarm optimization, and when the vibration signal modulation program based on particle swarm optimization is executed by a processor, processes and steps in the vibration signal modulation method based on particle swarm optimization provided in the embodiments of the present disclosure are implemented, and the same technical effect can be achieved. Details are not described herein again to avoid repetition.

Those skilled in the art may understand that all or part of the processes in the methods in the above embodiments may be implemented by instructing relevant hardware through a computer program, and the program may be stored in a computer-readable storage medium. When executed, the program may include the processes in the above method embodiments. The storage medium may be a magnetic disk, an optical disc, a read-only memory (ROM), a random access memory (RAM), or the like.

The above are merely the embodiments of the present disclosure. It should be noted herein that, for those skilled in the art, improvements can be made without departing from the creative concept of the present disclosure, but these all fall within the protection scope of the present disclosure.

What is claimed is:

1. A vibration signal modulation method based on particle swarm optimization, comprising the following steps:
setting a signal accelerating section parameter according to an expected vibration signal of an application object;
setting a corresponding signal braking section parameter and a signal braking section parameter range according to the signal accelerating section parameter, constructing, based on the signal braking section parameter range, a braking section initial particle parameter for a particle swarm algorithm, and performing, based on the particle swarm algorithm, an iterative search within the signal braking section parameter range to obtain an optimum braking parameter; and
superposing a signal corresponding to the optimum braking parameter on a signal corresponding to the signal accelerating section parameter to obtain a final vibration signal for the application object.

2. The vibration signal modulation method based on particle swarm optimization as described in claim 1, wherein a particle swarm parameter comprises: a maximum iteration generation, a preset iteration stop condition, a population number, a variable number, and an update constant;
default configuration parameters for the particle swarm algorithm comprises: a signal sampling rate, an actuator resonant frequency, a vibrator maximum displacement, and an actuator parameter;
the signal accelerating section parameter comprises: a signal production frequency, an accelerating section cycle, and an accelerating section voltage; and
the signal braking section parameter comprises: a braking cycle, a braking voltage, and a braking start position.

3. The vibration signal modulation method based on particle swarm optimization as described in claim 2, wherein the step of setting the corresponding signal braking section parameter and the signal braking section parameter range according to the signal accelerating section parameter, constructing, based on the signal braking section parameter range, the braking section initial particle parameter for the particle swarm algorithm, and performing, based on the particle swarm algorithm, the iterative search within the signal braking section parameter range to obtain the optimum braking parameter comprises the following sub-steps:
setting the corresponding signal braking section parameter and the signal braking section parameter range according to the signal accelerating section parameter, and constructing, based on the signal braking section parameter range, the braking section initial particle parameter for the particle swarm algorithm;
superposing a single-frequency signal generated according to the signal accelerating section parameter on a single-frequency signal generated according to the signal braking section parameter for integration to obtain an excitation electrical signal, driving the excitation electrical signal to the application object to obtain an acceleration waveform, and calculating a tailing factor of the acceleration waveform;
determining a current-generation best particle of the particle swarm algorithm based on the tailing factor, the current-generation best particle comprising a global best particle and personal best particles, and setting the signal braking section parameter range used to constrain the signal braking section parameter, wherein, if a number of iterations of the particle swarm algorithm is 1, the braking section initial particle parameter is taken as an personal best particle, and one of the personal best particles with a minimum tailing factor is taken as the global best particle;
performing, within the signal braking section parameter range, an update search of the particle swarm algorithm with the current-generation best particle, calculating an update speed and an update position of a current particle based on the current-generation best particle to obtain a next-generation particle, and calculating a tailing factor corresponding to the next-generation particle to obtain a next-generation best particle; and
determining whether a tailing factor of the next-generation best particle satisfies the preset iteration stop condition;
if not, updating the global best particle and the personal best particles with the next-generation best particle, which is taken as a new current-generation best particle to iteratively perform an update search; and
if yes, outputting the next-generation best particle as the optimum braking parameter.

4. The vibration signal modulation method based on particle swarm optimization as described in claim 3, wherein it is defined that the update speed is Vₖ and the update position is popₖ, and the following relations are satisfied:
$${V}_{k} = w \cdot {V}_{k - 1} + c 1 \cdot rand ( pbest - {pop}_{k - 1} ) + c 2 \cdot rand ( gbest - {pop}_{k - 1} ) ; \\ {pop}_{k} = {pop}_{k - 1} + {V}_{k} ;$$
where gbest denotes the global best particle, pbest denotes the personal best particle, k denotes an iteration generation of the particle swarm algorithm, rand( ) denotes a random number generation function, c1 and c2 denote the update constants, w denotes a preset weight, and the preset weight w satisfies:
$$w = \frac{maxgen - k}{maxgen} * ( 0.4 - 0.9 ) + 0.9 ;$$
maxgen denotes the maximum iteration generation.

5. The vibration signal modulation method based on particle swarm optimization as described in claim 3, wherein the update position and the signal accelerating section parameter are integrated to obtain an excitation signal, a vibrator displacement of the application object is calculated, and if the vibrator displacement is greater than the vibrator maximum displacement,
the braking cycle and the braking voltage are compressed; or
the braking voltage is reversely varied.

6. The vibration signal modulation method based on particle swarm optimization as described in claim 3, wherein the preset iteration stop condition is specifically:
the tailing factor corresponding to the optimum next-generation particle satisfying a preset stop ratio, or the current iteration generation satisfying the maximum iteration generation.

7. A vibration signal modulation system based on particle swarm optimization, comprising:
a parameter setting module configured to set a signal accelerating section parameter according to an expected vibration signal of an application object;
a particle swarm optimization module configured to set a corresponding signal braking section parameter and a signal braking section parameter range according to the signal accelerating section parameter, construct, based on the signal braking section parameter range, a braking section initial particle parameter for a particle swarm algorithm, and perform, based on the particle swarm algorithm, an iterative search within the signal braking section parameter range to obtain an optimum braking parameter; and
an output module configured to superpose a signal corresponding to the optimum braking parameter on a signal corresponding to the signal accelerating section parameter to obtain a final vibration signal for the application object.

8. The vibration signal modulation system based on particle swarm optimization as described in claim 7, wherein a particle swarm parameter comprises: a maximum iteration generation, a preset iteration stop condition, a population number, a variable number, and an update constant;
default configuration parameters for the particle swarm algorithm comprises: a signal sampling rate, an actuator resonant frequency, a vibrator maximum displacement, and an actuator parameter;
the signal accelerating section parameter comprises: a signal production frequency, an accelerating section cycle, and an accelerating section voltage; and
the particle swarm optimization module is specifically configured to:
set the corresponding signal braking section parameter and the signal braking section parameter range according to the signal accelerating section parameter, and construct, based on the signal braking section parameter range, the braking section initial particle parameter for the particle swarm algorithm;
superpose a single-frequency signal generated according to the signal accelerating section parameter on a single-frequency signal generated according to the signal braking section parameter for integration to obtain an excitation electrical signal, drive the excitation electrical signal to the application object to obtain an acceleration waveform, and calculate a tailing factor of the acceleration waveform;
determine a current-generation best particle of the particle swarm algorithm, the current-generation best particle comprising a global best particle and personal best particles, and set the signal braking section parameter range used to constrain the signal braking section parameter, wherein, if a number of iterations of the particle swarm algorithm is 1, the braking section initial particle parameter is taken as an personal best particle, and one of the personal best particles with a minimum tailing factor is taken as the global best particle;
perform, within the signal braking section parameter range, an update search of the particle swarm algorithm with the current-generation best particle, calculate an update speed and an update position of a current particle based on the current-generation best particle to obtain a next-generation particle, and calculate a tailing factor corresponding to the next-generation particle to obtain a next-generation best particle; and
determine whether a tailing factor of the next-generation best particle satisfies the preset iteration stop condition:
if not, update the global best particle and the personal best particles with the next-generation best particle, which is taken as a new current-generation best particle to iteratively perform an update search; and
if yes, output the next-generation best particle as the optimum braking parameter.

9. A computer-readable storage medium, storing thereon a vibration signal modulation program based on particle swarm optimization, wherein steps in the vibration signal modulation method based on particle swarm optimization as described in claim 1 are implemented when the vibration signal modulation program based on particle swarm optimization is executed by a processor.
